(19) United States
(12) Patent Application Publication
(10) Pub. No.: US 2010/0189144 A1
(43) Pub. Date: Jul. 29, 2010

(54) SEMICONDUCTOR LASER APPARATUS

(76) Inventors: Kazuya WAKABAYASHI, Kanagawa (JP); Daisuke IMANISHI, Kanagawa (JP)

Correspondence Address: FROMMER LAWRENCE & HAUG LLP, 745 FIFTH AVENUE, NEW YORK, NY, 10151, US

(21) Appl. No.: 12/688,202

(22) Filed: Jan. 15, 2010

(30) Foreign Application Priority Data
Jan. 23, 2009 (JP) P2009-013103

(51) Int. Cl. H01S 5/024; H01S 3/04

(52) U.S. Cl. 372/36; 372/43.01

(57) ABSTRACT

A semiconductor laser apparatus includes a heat dissipating member including a main body having a front end portion that extends in a left-right direction and a pair of protruding portions that protrude forward from both sides of the front end portion; a semiconductor laser device bonded along the front end portion of the main body; and a stiffener configured to bridge the pair of protruding portions.

### BACKGROUND OF THE INVENTION

1. Field of the Invention

The present invention relates to a semiconductor laser apparatus obtained by mounting a semiconductor laser device on a heat dissipating member such as a heat sink. 2. Description of the Related Art

In apparatuses for which semiconductor lasers are used, a problem related to generation of heat has become serious, which limits the application of semiconductor lasers in various fields. This problem concerns generated heat per unit area in semiconductor lasers and causes phenomena such as a temperature increase around a semiconductor laser and generation of stress due to thermal cycling. Such phenomena decrease the light-emitting output and light-emitting efficiency of semiconductor lasers and shorten the life thereof. Furthermore, such phenomena degrade laser characteristics, that is, light emitted from semiconductor lasers is shifted to longer wavelengths. Therefore, in apparatuses to which semiconductor lasers are applied, heat is efficiently emitted by bonding a semiconductor laser to a heat dissipating member (heat sink) having high thermal conductivity.

To increase the efficiency of heat emission, it is desirable to directly bond a semiconductor laser to a heat sink. Welding that uses soldering or the like is used as the bonding method. In this case, a metallic material is heated to high temperature to be melted and then cooled to be solidified. In general, since the difference in a coefficient of linear expansion between the material of a heat sink and the material of a semiconductor laser is large, a large thermal stress is generated due to the difference through the heating and cooling steps during bonding. In particular, a delicate semiconductor laser array or the like formed on a GaAs substrate does not withstand thermal stress and sometimes breaks.

To prevent the breakdown of a semiconductor laser due to such a thermal stress, a method in which a stress relaxation material is provided between a semiconductor laser and a heat sink is often used. A material having a lower coefficient of linear expansion and higher thermal conductivity than a heat sink is used as the stress relaxation material. For example, when a heat sink is composed of copper (Cu), aluminum nitride (AlN) or silicon carbide (SiC) is used for the stress relaxation material.

However, the above-described stress relaxation material normally has lower thermal conductivity than a heat sink. Therefore, when the stress relaxation material is used, the efficiency of heat emission is insufficient compared with the case where a semiconductor laser is directly bonded to a heat sink. There is proposed a method for relaxing the stress generated on a semiconductor laser by further disposing another heat dissipating member on the semiconductor laser through bridging while the semiconductor laser is directly bonded to a heat sink (Japanese Unexamined Patent Application Publication No. 2007-305977).

### SUMMARY OF THE INVENTION

However, in the method disclosed in Japanese Unexamined Patent Application Publication No. 2007-305977, a stress can be relaxed due to the bridged structure without decreasing the efficiency of heat emission, but the method poses a problem in that a deformation such as warpage is caused on a semiconductor laser.

In view of the foregoing problem, it is desirable to provide a semiconductor laser apparatus that has a high efficiency of heat emission and can suppress the deformation of a semiconductor laser.

A semiconductor laser apparatus according to an embodiment of the present invention includes a heat dissipating member including a main body having a front end portion that extends in a left-right direction and a pair of protruding portions that protrude forward from both sides of the front end portion; a semiconductor laser device bonded along the front end portion of the main body; and a stiffener configured to bridge the pair of protruding portions.

In the semiconductor laser apparatus according to an embodiment of the present invention, the semiconductor laser device is bonded along the front end portion of the main body in the heat dissipating member, whereby the heat is efficiently emitted during the operation, for example, compared with the case where a stress relaxation material or the like is inserted between the heat dissipating member and the semiconductor laser device. When the semiconductor laser device is bonded (mounted) to the main body, welding that uses soldering or the like is performed. Therefore, they are heated to high temperature and then cooled. There is normally a large difference in a coefficient of linear expansion between the semiconductor laser device and the heat dissipating member, which causes a large difference in shrinkage between the semiconductor laser device and the heat dissipating member in the cooling step. As a result, when the semiconductor laser device is directly bonded to the heat dissipating member, a large stress is generated on the semiconductor laser device. In the present invention, in the heat dissipating member, the stiffener bridges the pair of protruding portions that protrude forward from both sides of the front end portion, whereby the difference in shrinkage between the semiconductor laser device and the heat dissipating member is reduced and a stress is not easily generated in the semiconductor laser device.

In particular, assuming that a coefficient of linear expansion of the heat dissipating member is α1, a coefficient of linear expansion of the semiconductor laser device is α2, and a coefficient of linear expansion of the stiffener is α3, preferably α1>α2 and α1>α3 are satisfied, more preferably α1>α2>α3 is satisfied. When α1>α2, the shrinkage of the heat dissipating member is larger than that of the semiconductor laser device in the cooling step during the bonding. If the shrinkage of the stiffener is smaller than that of the heat dissipating member (α1>α3), the pair of protruding portions do not easily shrink and thus the shrinkage of the heat dissipating member is suppressed. The shrinkage of the protruding portions is further suppressed when α2>α3 is satisfied. Thus, a stress caused by the shrinkage of the heat dissipating member is not easily generated in the semiconductor laser device. Herein, a coefficient of linear expansion of the semiconductor laser device means a coefficient of linear expansion of a substrate material constituting the semiconductor laser device.

In the semiconductor laser apparatus according to an embodiment of the present invention, the semiconductor laser device is bonded along the front end portion of the main body of the heat dissipating member while the pair of protruding portions are disposed on both sides of the front end portion, the protruding portions being bridged by the stiffener. Thus, the heat from the semiconductor laser device is sufficiently emitted and the generation of stress in the semiconductor laser device during the bonding can be suppressed. Therefore, the deformation of a semiconductor laser can be suppressed while a high efficiency of heat emission is achieved.

### BRIEF DESCRIPTION OF THE DRAWINGS

FIG. 1 is a perspective view schematically showing a semiconductor laser apparatus according to an embodiment of the present invention;

FIG. 2 is a plan view schematically showing the semiconductor laser apparatus shown in FIG. 1;

FIG. 3 is a diagram showing a method for manufacturing the semiconductor laser apparatus shown in FIG. 1;

FIG. 4 is a diagram showing a manufacturing step that follows the step shown in FIG. 3;

FIG. 5 is a perspective view schematically showing a semiconductor laser apparatus according to a modification 1;

FIG. 6 is a diagram showing a method for manufacturing the semiconductor laser apparatus shown in FIG. 5;

FIG. 7 is a diagram showing a manufacturing step that follows the step shown in FIG. 6;

FIG. 8 is a plan view schematically showing a semiconductor laser apparatus according to a modification 2; and

FIG. 9 is a perspective view schematically showing a semiconductor laser apparatus according to a modification 3.

### DESCRIPTION OF THE PREFERRED EMBODIMENTS

An embodiment of the present invention will be described in detail with reference to the attached drawings. The embodiment is described in the following order.
(1) Embodiment: Example in which a semiconductor laser and stiffeners are bonded (soldered) to a heat sink in a single step
(2) Modification 1: Example in which a semiconductor laser and stiffeners are bonded (brazed, soldered) to a heat sink in multiple steps
(3) Modification 2: Example in which a stiffener is disposed on only the semiconductor laser array side
(4) Modification 3: Example in which tapering is formed on a stiffener

### 1. Structure of Semiconductor Laser Apparatus 1

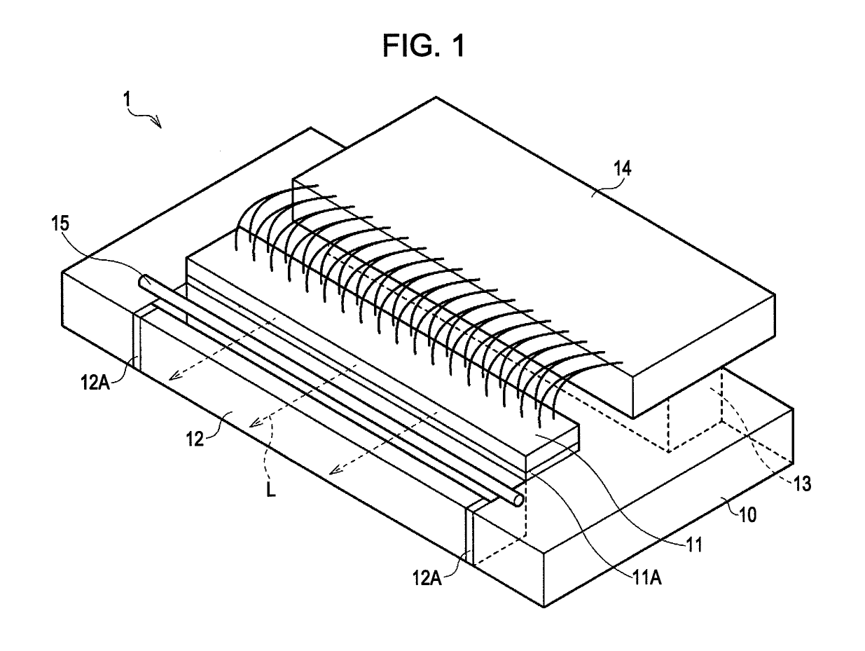

FIG. 1 shows a schematic structure of a semiconductor laser apparatus 1 according to an embodiment of the present invention. The semiconductor laser apparatus 1 is obtained by bonding a semiconductor laser array 11 to a heat sink 10 (heat dissipating member). The heat sink 10 is formed into a predetermined shape (the detail is described later). Stiffeners 12 and 13 are bonded to the heat sink 10 in the same plane as that of the heat sink 10. The semiconductor laser array 11 is connected to an electrode member 14 for external connection through wire bonding. A collimating lens 15 configured to condense laser beams L is disposed on the side, from which the laser beams L are emitted, of the semiconductor laser array 11 disposed on the heat sink 10. Hereinafter, the direction in which the laser beams L are emitted is the front.

The semiconductor laser array 11 is composed of, for example, a plurality of semiconductor laser devices (e.g., 25 devices) arranged in a single direction (herein, a left-right direction) and is bonded to the heat sink 10 through a metal layer 11A (first metal layer). The metal layer 11A is composed of a bonding metal such as solder or a metallic material having a melting point of, for example, about 300° C. or less, that is, an alloy containing gold (Au) or tin (Sn). In the semiconductor laser array 11, for example, the width in a left-right direction (arrangement direction) is 10 mm, the cavity length is 200 μm to 1.5 mm, and the thickness is 100 μm. The semiconductor laser array 11 is a red light-emitting laser having an emission wavelength of, for example, 630 to 690 μm.

An example of the red light-emitting laser includes a laser in which a semiconductor layer is formed on a substrate made of gallium arsenide (GaAs). The semiconductor layer is obtained by stacking, for example, a lower cladding layer, an active layer, an upper cladding layer, and a current injection layer and is composed of an AlGaInP compound semiconductor or the like. The AlGaInP compound semiconductor is a quaternary semiconductor containing at least one of aluminum (Al) and gallium (Ga) and at least one of indium (In) and phosphorus (P). Examples of the quaternary semiconductor include AlGaInP mixed crystals, GaInP mixed crystals, and AlInP mixed crystals. These mixed crystals optionally include an n-type impurity such as silicon (Si) or selenium (Se) or a p-type impurity such as magnesium (Mg), zinc (Zn), or carbon (C). In addition, a p-side electrode is formed on one side of the semiconductor laser array 11 and an n-side electrode is formed on the other side.

The heat sink 10 increases the heat emission effect of the semiconductor laser array 11 and preferably has good thermal conductivity and good electric conductivity. With thermal conductivity, a large amount of heat produced from the semiconductor laser array 11 can be dissipated and appropriate temperature is maintained in the semiconductor laser array 11. With electric conductivity, an electric current can be effectively conducted to the semiconductor laser array 11. Examples of the material of the heat sink 10 include elemental metals such as copper, aluminum (Al), tungsten (W), and molybdenum (Mo) and the alloys thereof. Examples of the alloys include a copper-tungsten alloy (Cu—W) and a copper-molybdenum alloy (Cu—Mo). In view of thermal conductivity and electric conductivity, the heat sink 10 is preferably composed of copper and an alloy containing copper. To further increase the electric conductivity, the heat sink 10 may be coated with, for example, gold (Au). The heat sink 10 has a thickness of, for example, 3.0 to 10.0 mm.

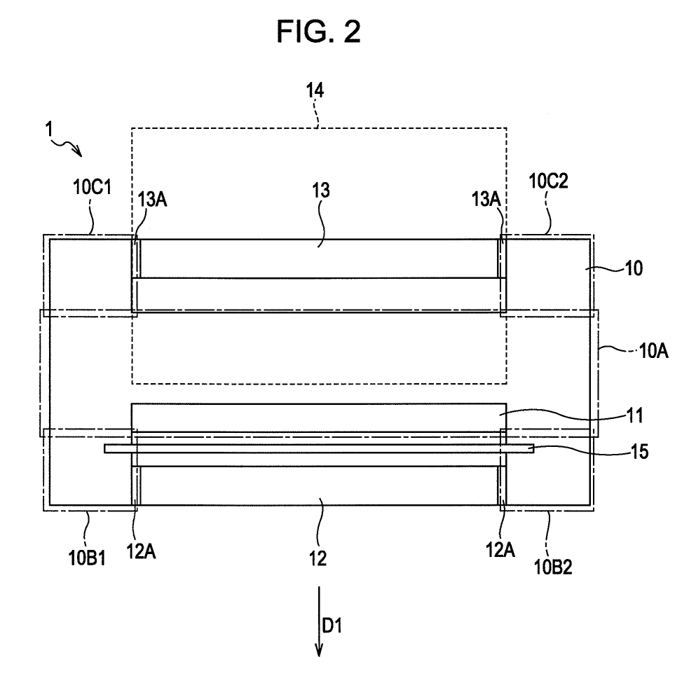

FIG. 2 is a plan view of the semiconductor laser apparatus 1. The heat sink 10 includes a main body 10A having a rectangular shape in plan view. Two pairs of protruding portions 10B1 and 10B2 and 10C1 and 10C2 protrude from the four corners of the main body 10A in forward and backward directions. The main body 10A is a principal portion as a heat dissipating member of the semiconductor laser array 11 and includes a front end portion and a rear end portion that each extends in a left-right direction. The semiconductor laser array 11 is bonded to the main body 10A along the front end portion.

The protruding portions 10B1 and 10B2 protrude forward from both sides of the front end portion so as to face each other. The protruding portions 10B1 and 10B2 are bridged by the stiffener 12. The protruding portions 10C1 and 10C2 protrude backward from both sides of the rear end portion so as to face each other. The protruding portions 10C1 and 10C2 are bridged by the stiffener 13.

The stiffener 12 is bonded to the surfaces of the protruding portions 10B1 and 10B2 through metal layer 12A (second metal layer), the surfaces facing opposite ends of the stiffener 12. The stiffener 13 is bonded to the surfaces of the protruding portions 10C1 and 10C2 through metal layer 13A (second metal layer), the surfaces facing opposite ends of the stiffener 13. The stiffeners 12 and 13 are disposed so as to be apart from the main body 10A, whereby there are spaces between the main body 10A and the stiffeners 12 and 13. A collimating lens 15 is disposed in the space of the front. For example, the metal layers 12A and 13A are composed of a metallic material having the same or substantially the same melting point as that of the metal layer 11A described above.

In this embodiment, the protruding portions 10B1 and 10B2 and the stiffener 12 are disposed on the front end portion of the main body 10A and the protruding portions 10C1 and 10C2 and the stiffener 13 are disposed on the rear end portion. In other words, the planar shape constituted by the heat sink 10 and the stiffeners is line symmetrical.

The stiffeners 12 and 13 reduce the difference in shrinkage between the heat sink 10 and the semiconductor laser array 11 in accordance with the relationship of a coefficient of linear expansion between the heat sink 10 and the semiconductor laser array 11. Specifically, when the coefficient of linear expansion of the heat sink 10 is larger than that of the semiconductor laser array 11, the stiffeners 12 and 13 suppress the shrinkage of the heat sink 10. In contrast, when the coefficient of linear expansion of the heat sink 10 is smaller than that of the semiconductor laser array 11, the stiffeners 12 and 13 facilitate the shrinkage of the heat sink 10. The stiffeners 12 and 13 are composed of, for example, a material shown in Table 1. The material of the stiffeners 12 and 13 is preferably selected in accordance with the materials of the heat sink 10 and the semiconductor laser array 11.

TABLE 1

| | Coefficient of Linear |
|---|---|
| Name of Material | Expansion (×10⁻⁶/° C.) |
| Silicic acid anhydride (SiO₂) | 0.5 |
| Diamond (C) | 1.1 |
| Pyrex glass | 3.2 |
| Tungsten (W) | 4.3 |
| Aluminum nitride (AlN) | 4.5 |
| Silicon carbide (SiC) | 6.6 |
| Chromium (Cr) | 6.8 |
| Hard glass | 8.5 |
| Platinum (Pt) | 9.0 |
| Magnesium oxide (MgO) | 9.7 |
| Antimony (Sb) | 12 |
| Iron (Fe, including stainless alloy) | 10 to 18 |
| Cobalt (Co) | 12.4 |
| Nickel (Ni) | 12.8 |
| Bismuth (Bi) | 13.3 |
| Gold (Au) | 14.3 |
| Copper (Cu) | 16.8 |
| Aluminum (Al) | 23 (25) |

For example, the coefficient of linear expansion of the heat sink 10 is defined as α1, the coefficient of linear expansion of the semiconductor laser array 11 is defined as α2, and the coefficient of linear expansion of the stiffener 12 is defined as α3. When α1>α2, the stiffener 12 is composed of a material that preferably satisfies α1>α3, more preferably α2>α3 (that is, α1>α2>α3). Specifically, when the heat sink 10 is composed of copper (α1=16.8×10⁻⁶/° C.) and the above-described red light-emitting laser (α2=5.9×10⁻⁶/° C.) including a GaAs substrate is used for the semiconductor laser array 11, the stiffeners 12 and 13 are preferably composed of a material such as diamond (C), tungsten, silicon carbide, aluminum nitride, chromium (Cr), platinum (Pt), magnesium oxide (MgO), antimony (Sb), iron, cobalt (Co), nickel (Ni), or bismuth (Bi) (α1>α3). Among them, diamond (C), tungsten, and aluminum nitride are more preferable materials (α2>α3). Herein, the coefficient α2 of linear expansion of the semiconductor laser array 11 means a coefficient of linear expansion of a substrate material constituting the semiconductor laser array 11.

The electrode member 14 is composed of, for example, copper covered with gold or the like. The thickness is, for example, 1.0 to 3.0 mm. The collimating lens 15 condenses the laser beams L emitted from the semiconductor laser array 11 and guides the laser beams L in a desired direction. By disposing the collimating lens 15 in a position closer to the semiconductor laser array 11 than the stiffener 12, part of the laser beams L can be prevented from being blocked by the stiffener 12 and thus being lost.

### 2. Method for Manufacturing Semiconductor Laser Apparatus 1

For example, the above-described semiconductor laser apparatus 1 can be manufactured as follows.

First, a semiconductor laser array 11 is manufactured. For example, a compound semiconductor layer is formed on a substrate composed of GaAs by metal organic chemical vapor deposition (MOCVD) or molecular beam epitaxy (MBE). Herein, for example, trimethylaluminum (TMA), trimethylgallium (TMG), trimethylindium (TMIn), or phosphine (PH₃) is used as a raw material of the AlGaInP compound semiconductor described above. For example, hydrogen selenide (H₂Se) is used as a raw material of a donor impurity and dimethylzinc (DMZ) is used as a raw material of an acceptor impurity. Subsequently, electrodes are formed on the surface of the formed compound semiconductor layer and on the back of the GaAs substrate by vapor deposition or sputtering. A semiconductor laser array 11 is then formed by disposing a reflector film (not shown) on a pair of end faces in an axial direction.

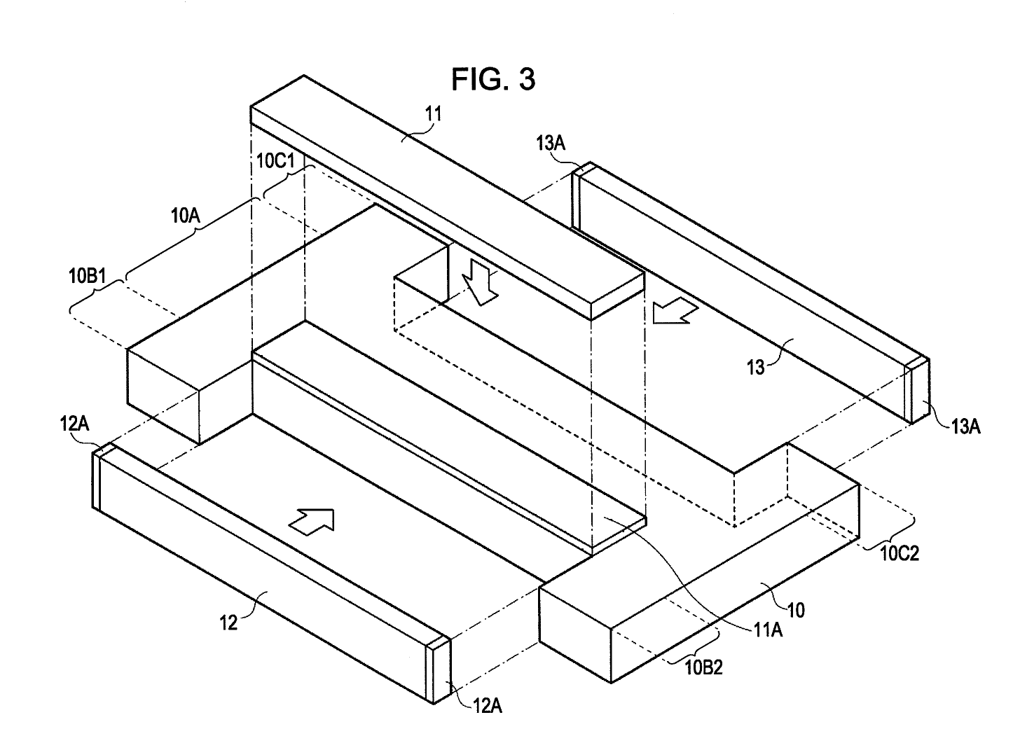

As shown in FIG. 3, a heat sink 10 is formed so as to have the planar shape described above. A metal layer 11A composed of the material described above is formed by depositing, for example, gold and tin in sequence by vacuum deposition, plating, or the like on the formed heat sink 10 in a region (front end portion of a main body 10A) where the semiconductor laser array 11 is to be bonded. Herein, a region other than the above-described region on the heat sink 10 may be masked to prevent a metallic material from being deposited. On the other hand, metal layers 12A and 13A are formed by depositing, for example, gold and tin in sequence by vacuum deposition, plating, or the like on opposite ends of stiffeners 12 and 13 composed of the material described above. Subsequently, the semiconductor laser array 11 is aligned with the metal layer 11A formed on the heat sink 10 and then laid on the metal layer 11A. At the same time, the stiffener 12 having the metal layers 12A is inserted into a space between a pair of protruding portions 10B1 and 10B2. The stiffener 13 having the metal layers 13A is inserted into a space between a pair of protruding portions 10C1 and 10C2. Herein, spaces are formed between the main body 10A of the heat sink 10 and the inserted stiffeners 12 and 13.

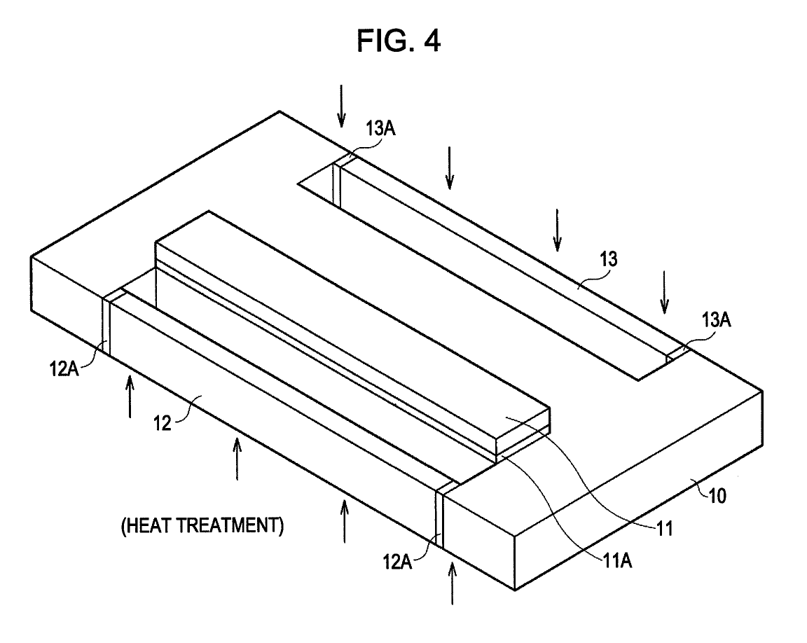

As shown in FIG. 4, heat treatment is performed on the heat sink 10 on which the semiconductor laser array 11 and the stiffeners 12 and 13 have been arranged, for example, at about 300° C. or less to melt the metal layer 11A and the metal layers 12A and 13A. The metal layer 11A and the metal layers 12A and 13A are then solidified by cooling. As a result, the semiconductor laser array 11 is bonded to the main body 10A and the stiffeners 12 and 13 are respectively bonded to the pair of protruding portions 10B1 and 10B2 and the pair of protruding portions 10C1 and 10C2. Subsequently, a collimating lens 15 is attached on the protruding portions 10B1 and 10B2 using an ultraviolet curable resin or the like so as to be disposed in the space between the main body 10A and the stiffener 12. Finally, an electrode member 14 is disposed on the heat sink 10 and then connected to the semiconductor laser array 11 through wire bonding. Thus, the semiconductor laser apparatus 1 shown in FIGS. 1 and 2 is completed.

### 3. Operation and Advantage of Semiconductor Laser Apparatus 1

In this embodiment, the semiconductor laser array 11 is bonded to the heat sink 10 along the front end portion of the main body 10A without inserting a stress relaxation material. Thus, the heat in the semiconductor laser array 11 is efficiently emitted during the operation compared with the case where a stress relaxation material or the like is inserted. The semiconductor laser array 11 is bonded (mounted) to the heat sink 10 through the step of heating the heat sink 10 to a temperature at which the metal layer 11A is melted and the step of cooling the heat sink 10.

Herein, there is normally a large difference between the coefficient al of linear expansion of the heat sink 10 and the coefficient α2 of linear expansion of the semiconductor laser array 11, which causes a large difference in shrinkage between the semiconductor laser array 11 and the heat sink 10 in the cooling step. Consequently, if the semiconductor laser array 11 is directly bonded to the heat sink 10, a large stress caused by the difference in shrinkage is generated in the semiconductor laser array 11.

In the heat sink 10 of this embodiment, however, the pair of protruding portions 10B1 and 10B2 are formed on both sides of the front end portion to which the semiconductor laser array 11 has been bonded and the protruding portions 10B1 and 10B2 are bridged by the stiffener 12. This reduces the difference in shrinkage between the semiconductor laser array 11 and the heat sink 10. Thus, the stress described above is not easily generated in the semiconductor laser array 11.

In particular, when the heat sink 10 is composed of copper and a red light-emitting laser including a GaAs substrate is used for the semiconductor laser array 11, that is, when α1>α2, the stiffener 12 may be composed of a material that satisfies α1>α3, preferably α1>α2>α3. When α1>α2, the shrinkage of the heat sink 10 is larger than that of the semiconductor laser array 11 in the cooling step. If the shrinkage of the stiffener 12 is smaller than that of the heat sink 10 (α1>α3), the protruding portions 10B1 and 10B2 are relatively pressed toward the outer side of the heat sink 10 and thus the shrinkage of the heat sink 10 is suppressed. The shrinkage is further suppressed when α2>α3 is satisfied. Thus, a stress caused by the shrinkage of the heat sink 10 is not easily generated in the semiconductor laser array 11.

As described above, in this embodiment, the semiconductor laser array 11 is bonded to the front end portion of the main body 10A of the heat sink 10 while the pair of protruding portions 10B1 and 10B2 are disposed on both sides of the front end portion, the protruding portions 10B1 and 10B2 being bridged by the stiffener 12. Thus, the heat from the semiconductor laser array 11 is sufficiently emitted and the generation of stress in the semiconductor laser array 11 during the bonding can be suppressed. Therefore, the deformation of a semiconductor laser can be suppressed while a high efficiency of heat emission is achieved.

In this embodiment, the protruding portions 10B1 and 10B2 and the bridging structure that uses the stiffener 12 are also disposed on the rear end portion of the main body 10A. In other words, by providing a line symmetric structure to the heat sink 10, the shrinkage of the heat sink 10 caused by the coefficient of linear expansion described above can be uniformly suppressed in a plane. Thus, the generation of stress in the semiconductor laser array 11 can be suppressed more effectively.

Furthermore, if the metal layers 11A, 12A, and 13A are each composed of the same metallic material, the semiconductor laser array 11 and the stiffeners 12 and 13 can be bonded to the heat sink 10 in a single step.

The metal layers 11A, 12A, and 13A may be composed of the same material as described above or may be composed of different materials. This means that the melting points of the metal layers may be different from each other. Even in this case, the heating step and the cooling step can be performed together by performing heating until all of the metal layers are melted and then by performing cooling until all of the metal layers are solidified. If the metal layers are each composed of a different metallic material, the melting points of the metal layers 12A and 13A are preferably higher than that of the metal layer 11A. This is because, by solidifying the metal layers 12A and 13A earlier than the metal layer 11A in the cooling step, the stiffeners 12 and 13 are bonded to the heat sink 10 and thus the shrinkage of the heat sink 10 during cooling can be effectively suppressed.

In the embodiment described above, the case where, after the metal layer 11A is formed on the heat sink 10, the semiconductor laser array 11 is aligned with the metal layer 11A has been described, but the metal layer 11A may be formed on the semiconductor laser array 11. Similarly, the case where the metal layers 12A are formed on opposite ends of the stiffener 12 and the metal layers 13A are formed on opposite ends of the stiffener 13 has been described, but the metal layers 12A may be formed on the surfaces of the protruding portions 10B1 and 10B2 of the heat sink 10, the surfaces opposing both the ends of the stiffener 12, and the metal layers 13A may be formed on the surfaces of the protruding portions 10C1 and 10C2, the surfaces opposing both the ends of the stiffener 13.

Next, modifications of the present invention will be described. Hereinafter, the same constituent elements as those in the embodiment described above are designated by the same reference numerals, and the descriptions are omitted.

### Modification 1

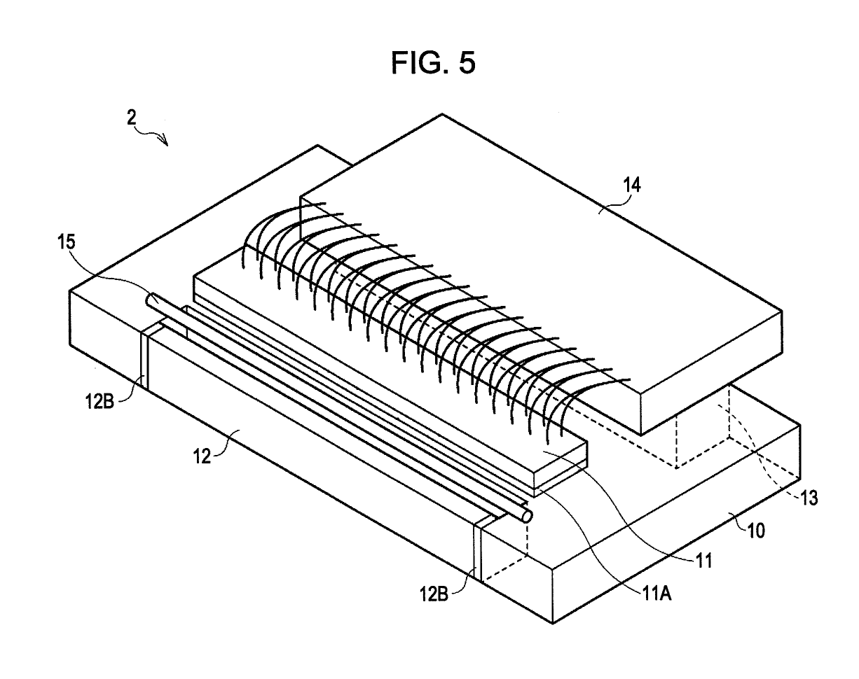

FIG. 5 shows a schematic structure of a semiconductor laser apparatus 2 according to a modification 1. The semiconductor laser apparatus 2 has the same structure as in the above-described embodiment except metal layers 12B that bond the stiffener 12 to the pair of protruding portions 1081 and 10B2 of the heat sink 10 and metal layers 13B that bond the stiffener 13 to the pair of protruding portions 10C1 and 10C2. The metal layers 12B and 13B are composed of a material having a higher melting point than the metal layer 11A, for example, a bonding metal having a melting point of about 750° C. or less such as a brazing filler metal. Such metal layers 12B and 13B are composed of tin-phosphor copper or the like.

For example, the semiconductor laser apparatus 2 can be manufactured as follows. First, a semiconductor laser array 11 is manufactured as in the semiconductor laser apparatus 1 of the embodiment described above. The metal layers 12B and 13B composed of, for example, the above-described material are formed on opposite ends of stiffeners 12 and 13 by vacuum deposition, plating, or the like. Subsequently, the stiffener 12 having the metal layers 12A is inserted into a space between the protruding portions 10B1 and 10B2 of the heat sink 10 having a predetermined planar shape. The stiffener 13 having the metal layers 13A is also inserted into a space between the protruding portions 10C1 and 10C2 of the heat sink 10. Herein, spaces are formed between a main body 10A of the heat sink 10 and the inserted stiffeners 12 and 13.

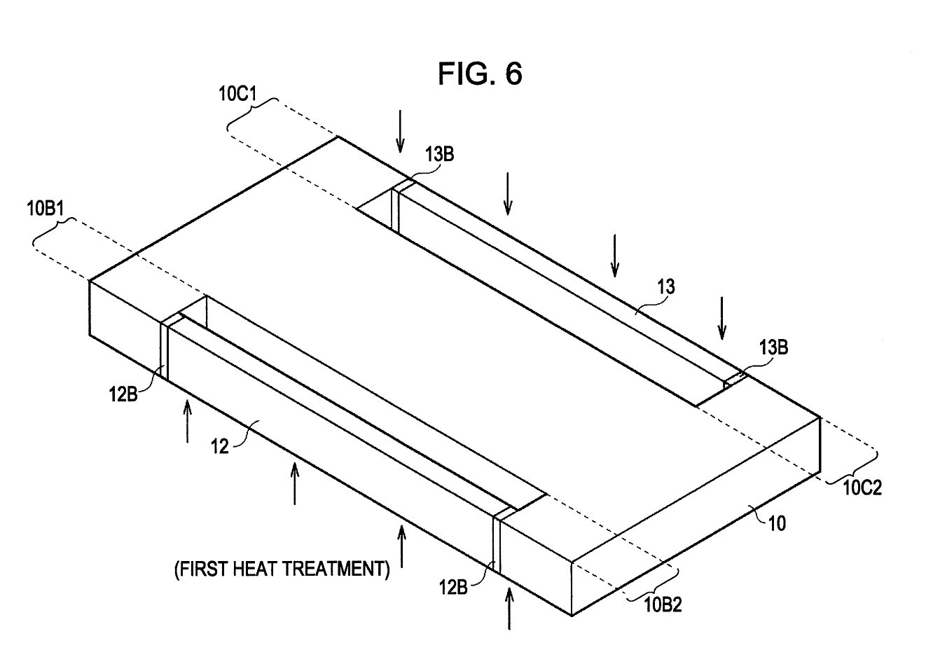

As shown in FIG. 6, heat treatment is performed on the heat sink 10 on which the stiffeners 12 and 13 have been arranged, for example, at about 750° C. or less to melt the metal layers 12B and 13B. The metal layers 12B and 13B are then solidified by cooling. As a result, the stiffeners 12 and 13 are respectively bonded to the pair of protruding portions 10B1 and 10B2 and the pair of protruding portions 10C1 and 10C2.

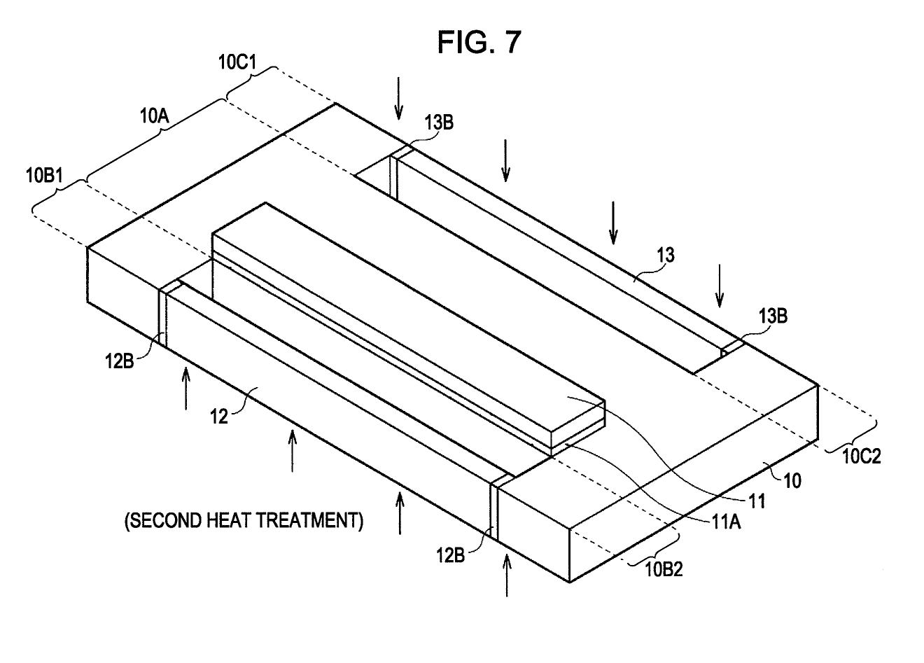

As shown in FIG. 7, a metal layer 11A is formed on the main body 10A of the heat sink 10 to which the stiffeners 12 and 13 have been bonded, as in the embodiment described above. The semiconductor laser array 11 is aligned with the metal layer 11A and then laid on the metal layer 11A. Subsequently, heat treatment is performed on the heat sink 10, for example, at about 300° C. or less to melt the metal layer 11A. The metal layer 11A is then solidified by cooling. Thus, the semiconductor laser array 11 is bonded to the main body 10A. Finally, an electrode member 14 is disposed on the heat sink 10 and then connected to the semiconductor laser array 11 as in the embodiment described above, whereby the semiconductor laser apparatus 2 shown in FIG. 5 is completed.

As described in the modification 1, the metal layers 12B and 13B for bonding the stiffeners 12 and 13 may be composed of a metallic material having a higher melting point than the metal layer 11A for bonding the semiconductor laser array 11. In other words, the case where the semiconductor laser array 11 and the stiffeners 12 and 13 are bonded to the heat sink 10 in a single step by using the same metallic material for the metal layers 11A, 12A, and 13A has been described in the above-described embodiment, but they may be bonded to the heat sink 10 in multiple steps as in the modification 1. Consequently, since the stiffeners 12 and 13 are solidified earlier than the semiconductor laser array 11, the deformation of the heat sink 10 can be effectively suppressed.

Modification 2

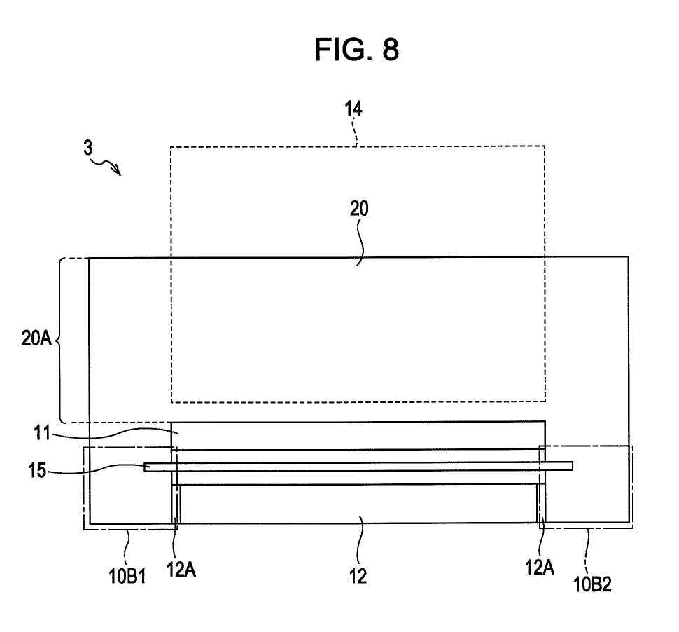

FIG. 8 is a plan view of a semiconductor laser apparatus 3 according to a modification 2. In a heat sink 20 of the semiconductor laser apparatus 3, a semiconductor laser array 11 is bonded to the front end portion of a main body 20A having a rectangular shape. A pair of protruding portions 10B1 and 10B2 are disposed on only both sides of the front end portion, and only a stiffener 12 is disposed in a space between the protruding portions 10B1 and 10B2. That is to say, a pair of protruding portions and a stiffener are not disposed on a rear end portion of the main body 20A.

As described above, the protruding portions 10B1 and 10B2 and the stiffener 12 are not necessarily disposed on the front end portion and the rear end portion, respectively, and the heat sink 20 does not necessarily have a line symmetric shape. However, the case where the protruding portions 10B1 and 10B2 and 10C1 and 10C2 and the stiffeners 12 and 13 are disposed on the front end portion and the rear end portion, respectively, as in the above-described embodiment is preferred because the deformation of the heat sink 10 can be uniformly suppressed in a plane.

Modification 3

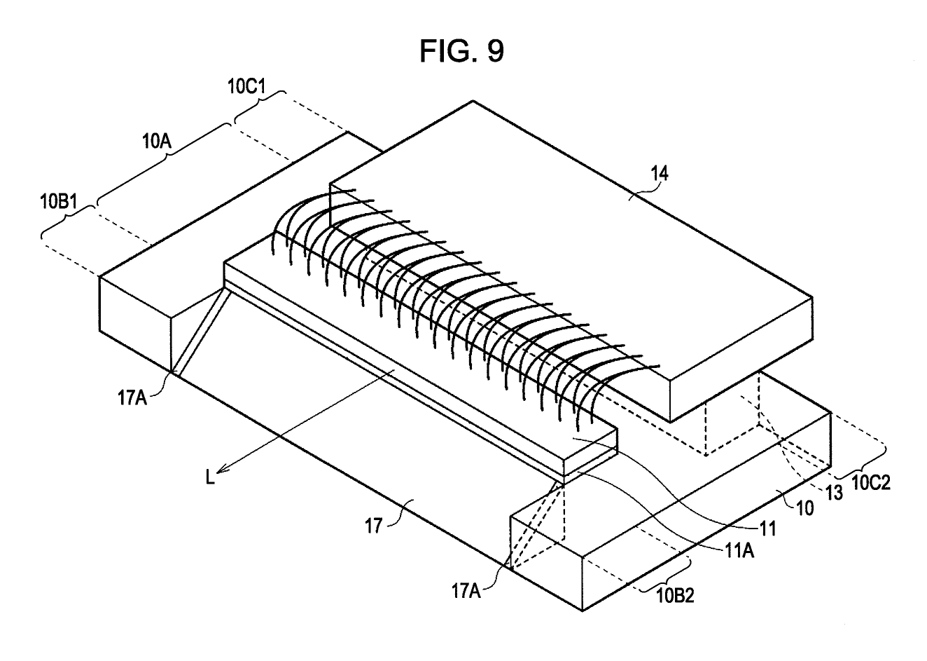

FIG. 9 shows a schematic structure of a semiconductor laser apparatus 4 according to a modification 3. The semiconductor laser apparatus 4 has the same structure as that of the semiconductor laser apparatus 1 of the above-described embodiment except that the collimating lens 15 is not disposed and a stiffener 17 has a different shape. In the modification 3, the upper surface of the stiffener 17 is tapered such that the thickness decreases as the distance from the light-emitting surface of the semiconductor laser array 11 increases. In other words, the stiffener 17 is formed into, for example, a triangular prism. The stiffener 13 that is the same as that of the above-described embodiment is disposed on the rear end portion of the main body 10A of the heat sink 10, but the shape of the stiffener 13 is not particularly limited. The stiffener 17 is composed of the same material as that of the stiffeners 12 and 13 of the above-described embodiment.

As described above, by providing a tapered surface to the stiffener 17 disposed on the light-emitting surface side of the semiconductor laser array 11 such that the thickness decreases as the distance from the light-emitting surface increases, the laser beams L can be prevented from being blocked by the stiffener 17. In the modification 3, since a collimating lens is not necessary, a space between the main body 10A of the heat sink 10 and the stiffener 17 is also not necessary.

The present invention has been described using the embodiment and modifications. However, the present invention is not limited to the above-described embodiment or the like, and various modifications can be made. For example, the case where the material of the heat sink has a larger coefficient of linear expansion than that of the semiconductor laser array (α1>α2) has been described in, for example, the above-described embodiment, but the present invention can be applied to the case where the material of the heat sink has a smaller coefficient of linear expansion than that of the semiconductor laser array (α1<α2). An example of the material of the heat sink includes tungsten and an example of the material of the semiconductor laser array includes gallium nitride (GaN, coefficient of linear expansion: 5.6×10⁻⁶/° C.). When α1<α2, the stiffener is composed of a material that satisfies α2<α3 such as iron. In this case, the shrinkage of the semiconductor laser array is larger than that of the heat sink in the cooling step during the bonding. Since the shrinkage of the stiffener is larger than that of the semiconductor laser array, the protruding portions are pulled inward by the stiffener, whereby the deformation (shrinkage) of the heat sink is facilitated.

The case where the first metal layer for bonding the semiconductor laser array has a melting point lower than or equal to that of the second metal layer for bonding the stiffener has been described in, for example, the above-described embodiment, but the first metal layer may be composed of a metallic material having a higher melting point than that of the second metal layer. In this case, the semiconductor laser array is bonded to the heat sink while the second metal layer of the stiffener is not solidified, but the same advantage as that of the present invention can be achieved if the stiffener is aligned with the heat sink with high precision.

The case where the light-emitting surface of the semiconductor laser array shares the same plane with the side face of the main body of the heat sink has been described in, for example, the above-described embodiment, but the light-emitting surface of the semiconductor laser array may protrude forward from the side face of the main body.

The case where the length of the semiconductor laser array in the longitudinal direction is the same as that of the stiffener has been described in, for example, the above-described embodiment, but the stiffener may be longer than the semiconductor laser array.

The case where a space is formed between the stiffener and the main body of the heat sink and the collimating lens is disposed in the space has been described in, for example, the above-described embodiment, but the collimating lens is not necessarily disposed. When the collimating lens is not disposed, the space is unnecessary.

The case where two stiffeners having the same shape and size are disposed on the side close to the semiconductor laser array and on the side further from the semiconductor laser array has been described in, for example, the above-described embodiment, but the two stiffeners do not necessarily have the same structure on both the sides. For example, a space is unnecessary on the side further from the semiconductor laser array because a collimating lens is not disposed. However, to uniformly suppress the shrinkage of the heat sink in a plane, the structures on both the sides are preferably symmetrical.

The case where the semiconductor laser array on which a plurality of semiconductor laser devices are arranged is bonded on the heat sink has been described in, for example, the above-described embodiment, but the plurality of semiconductor laser devices are not necessarily arranged. However, a single or a plurality of semiconductor laser devices preferably extend in a left-right direction on the front end portion of the main body of the heat sink.

The present invention has been described using an AlGaInP compound semiconductor laser as an example in the above-described embodiment or the like, but the present invention can be applied to other compound semiconductor lasers such as an AlInP or GaInAsP red light-emitting semiconductor laser, a GaInN or AlGaInN semiconductor laser (gallium nitride semiconductor laser), and a ZnCdMgSSeTe semiconductor laser (group II-VI semiconductor laser). The present invention can also be applied to semiconductor lasers whose oscillation wavelength is not necessarily in a visible region. Examples of the semiconductor lasers include AlGaAs, INGaAs, InP, and GaInAsNP semiconductor lasers.

The present application contains subject matter related to that disclosed in Japanese Priority Patent Application JP 2009-013103 filed in the Japan Patent Office on Jan. 23, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor laser apparatus comprising:
a heat dissipating member including a main body having a front end portion that extends in a left-right direction and a pair of protruding portions that protrude forward from both sides of the front end portion;
a semiconductor laser device bonded along the front end portion of the main body; and
a stiffener configured to bridge the pair of protruding portions.

2. The semiconductor laser apparatus according to claim 1, wherein, assuming that a coefficient of linear expansion of the heat dissipating member is al, a coefficient of linear expansion of the semiconductor laser device is α2, and a coefficient of linear expansion of the stiffener is α3, α1>α2 and α1>α3 are satisfied.

3. The semiconductor laser apparatus according to claim 2, wherein α1>α2>α3 is satisfied.

4. The semiconductor laser apparatus according to claim 1, further comprising:
a collimating lens disposed between the front end portion and the stiffener,
wherein the semiconductor laser device has a light-emitting surface that faces in a forward direction,
the stiffener is disposed in a position apart from the front end portion of the main body, and
the collimating lens opposes the light-emitting surface of the semiconductor laser device.

5. The semiconductor laser apparatus according to claim 1,
wherein the semiconductor laser device has a light-emitting surface that faces in a forward direction, and
a thickness of the stiffener decreases as a distance from the light-emitting surface increases.

6. The semiconductor laser apparatus according to claim 1,
wherein a first metal layer is formed between the semiconductor laser device and the main body, and
second metal layers are formed between opposite ends of the stiffener and surfaces of the pair of protruding portions, the surfaces facing the opposite ends of the stiffener.

7. The semiconductor laser apparatus according to claim 6, wherein the first metal layer and the second metal layers are composed of the same metallic material.

8. The semiconductor laser apparatus according to claim 6, wherein the first metal layer is composed of a metal having a lower melting point than that of the second metal layers.

9. The semiconductor laser apparatus according to claim 1, wherein the pair of protruding portions and the stiffener are also disposed on a rear end portion of the main body.

10. The semiconductor laser apparatus according to claim 9, wherein the heat dissipating member and the stiffener are disposed so as to be line symmetrical when viewed in plan.
